(19) United States
(12) Patent Application Publication
(10) Pub. No.: US 2026/0164768 A1
(43) Pub. Date: Jun. 11, 2026

(54) SEMICONDUCTOR DEVICE

(71) Applicant: ROHM CO., LTD., Kyoto (JP)

(72) Inventor: Kosaku ADACHI, Kyoto (JP)

(73) Assignee: ROHM CO., LTD., Kyoto (JP)

(21) Appl. No.: 19/182,259

(22) Filed: Apr. 17, 2025

(30) Foreign Application Priority Data
Apr. 26, 2024 (JP) 2024-072996

(51) Int. Cl. H10D 84/00; H10D 1/47

(52) U.S. Cl. CPC H10D 84/209; H10D 1/47

(57) ABSTRACT

A semiconductor device includes a semiconductor substrate, an insulating layer provided on the semiconductor substrate, a first high resistance unit embedded in the insulating layer and disposed so as to surround a first electrode in a plan view, a second high resistance unit embedded in the insulating layer and disposed so as to surround a second electrode in a plan view, and low resistance units for voltage detection that are electrically connected to the first high resistance unit and the second high resistance unit, and have lower resistances than the first high resistance unit and the second high resistance unit.

### CROSS REFERENCE TO RELATED APPLICATION

This application is based upon and claims the benefit of priority of the prior Japanese Patent Application No. 2024-072996, filed on Apr. 26, 2024, the entire contents of which are incorporated herein by reference.

### TECHNICAL FIELD

The present disclosure relates to a semiconductor device.

### BACKGROUND ART

WO 2023/085026 discloses a semiconductor device including a plurality of resistors in a chip.

### BRIEF DESCRIPTION OF THE DRAWINGS

FIG. 1 is a circuit diagram of a high voltage detection device.

FIG. 2A is a circuit diagram of a first example of resistors and FIG. 2B is a circuit diagram of a second example of resistors.

FIG. 3 is a plan view of a semiconductor package equipped with the high voltage detection device.

FIG. 4 is a plan view of a resistor chip.

FIG. 5 is a plan view of a resistor chip.

FIG. 6 is a graph showing the relationship between a distance r from the center of a first electrode or a second electrode, and a voltage V.

FIG. 7 is a plan view of a high resistance unit according to Embodiment 1.

FIG. 8 is a diagram showing a vertical cross-sectional configuration of the high resistance unit.

FIG. 9 is a plan view of a high resistance unit according to Embodiment 2.

FIG. 10 is a diagram showing a vertical cross-sectional configuration of the high resistance unit.

FIG. 11 is a plan view of a high resistance unit according to Embodiment 3.

FIG. 12 is a plan view of a high resistance unit according to Embodiment 4.

FIGS. 13A, 13B, and 13C are plan views of low resistance units for voltage detection.

### DETAILED DESCRIPTION OF EMBODIMENTS

Below, various exemplary embodiments will be described in detail with reference to the drawings. The same or corresponding components in the drawings are assigned the same reference characters and redundant explanations thereof will be omitted.

First, the basic structure of a high voltage detection device will be described.

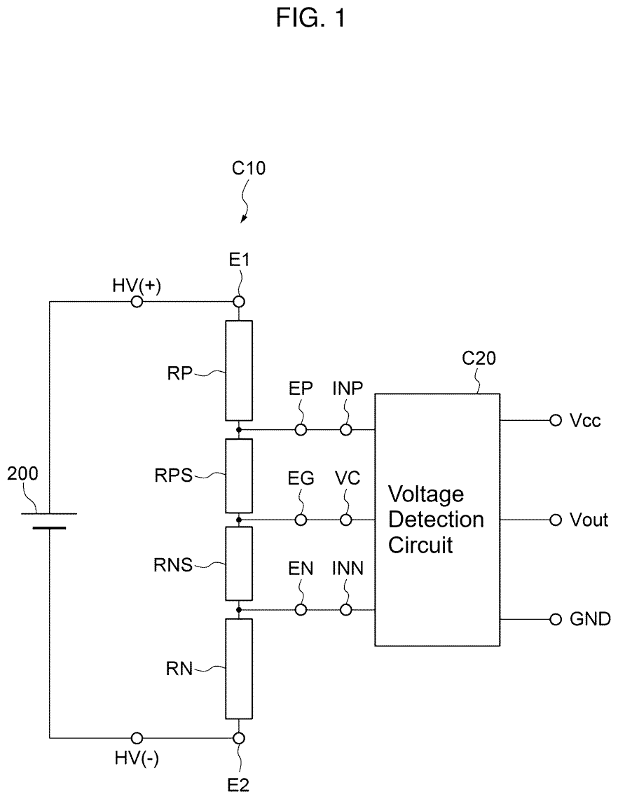

FIG. 1 is a circuit diagram of the high voltage detection device. The high voltage detection device includes a resistor circuit C10 (voltage-dividing circuit) and a voltage detection circuit C20. A first input terminal HV(+) of the resistor circuit C10 is electrically connected to the positive electrode of the battery 200. A second input terminal HV(−) of the resistor circuit C10 is electrically connected to the negative electrode of the battery 200. The first input terminal HV(+) is electrically connected to the first electrode E1 (electrode pad). The second input terminal HV(−) is electrically connected to the second electrode E2 (electrode pad).

The resistor circuit C10 includes a first high resistance unit RP (first resistor), a first low resistance unit RPS, a second low resistance unit RNS, and a second high resistance unit RN (second resistor). Between the first electrode E1 and the second electrode E2, the first high resistance unit RP, the first low resistance unit RPS, the second low resistance unit RNS, and the second high resistance unit RN are connected in series in the stated order. The first high resistance unit RP and the second high resistance unit RN have the function of lowering high voltage and each have a high resistance. The first low resistance unit RPS and the second low resistance unit RNS have the function of detecting voltage and each have a lower resistance than the high resistance units.

An example of a resistance of one high resistance unit is 500 MΩ, but can be 1 MΩ to 1,000 MΩ, inclusive. The resistance of the high resistance units can also be set to 100 MΩ to 800 MΩ, inclusive. The resistance of the high resistance units can also be set to 300 MΩ to 600 MΩ, inclusive. The resistances may be set to any value that allows for durability against high voltages and that allows for voltage detection.

The resistance of one low resistance unit (RPS or RNS) is K% or less of the resistance of the high resistance units. Examples of K include 5%, 3%, 1%, 0.5%, 0.3%, 0.1%, 0.05%, or 0.01%, and the resistance of the low resistance units can be set to 0.01 MΩ to 10 MΩ, for example.

The connection point between the first high resistance unit RP and the first low resistance unit RPS is electrically connected to the first output electrode EP (electrode pad). The connection point between the second high resistance unit RN and the second low resistance unit RNS is electrically connected to the second output electrode EN (electrode pad). A reference electrode EG (electrode pad) is electrically connected between the first low resistance unit RPS and the second low resistance unit RNS.

The resistor circuit C10 is a voltage-dividing circuit, and thus, a voltage based on the resistance at two selected points in the resistor circuit C10 can be attained. The first output electrode EP is electrically connected to a first input terminal INP of the voltage detection circuit C20. The second output electrode EN is electrically connected to a second input terminal INN of the voltage detection circuit C20. The reference electrode EG is electrically connected to a reference terminal VC of the voltage detection circuit C20. The potential of the reference terminal VC can be set to ground potential, for example. The voltage detection circuit C20 can output the output voltage Vout. The output voltage Vout can be the total of: a first potential difference between the first input terminal INP and the reference terminal VC; and a second potential difference between the second input terminal INN and the reference terminal VC. The voltage detection circuit C20 can include a source follower (amplifier) that

amplifies the voltage inputted from the input terminal, and can be provided with a differential amplifier circuit for attaining the total input voltage. The voltage detection circuit C20 includes an input terminal for the power source voltage Vcc for operating the internal circuit, and an input terminal for setting the ground potential GND.

The resistor circuit C10 can include a dummy resistor.

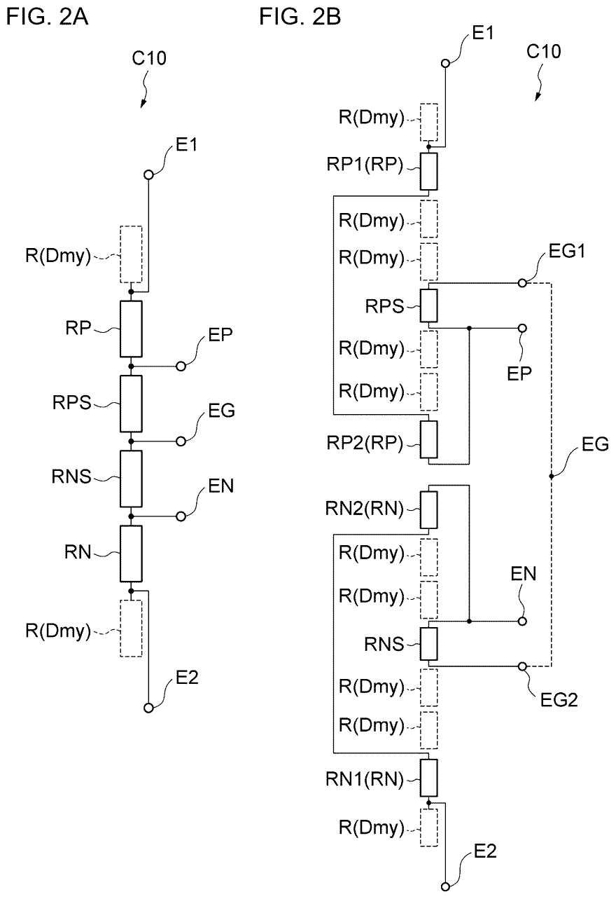

FIG. 2A is a circuit diagram of a first example of resistors and FIG. 2B is a circuit diagram of a second example of resistors.

In the resistor circuit C10 of FIG. 2A, the first end of a dummy resistor R(Dmy) is electrically connected to the input side of the first high resistance unit RP. A dummy resistor R(Dmy) is electrically connected to the input side of the second high resistance unit RN. The dummy resistor may alternatively not be electrically connected to a resistor. The resistors on both ends of the resistor chip sometimes differ in resistance characteristics compared to resistors towards the center, for example. The detection accuracy may be improved by using such resistors as dummy resistors.

The resistor circuit C10 of FIG. 2B has a configuration modified from that of the circuit of the first example. In this example, the first high resistance unit RP is constituted of a high resistance unit RP1 and a high resistance unit RP2 connected in series, and the second high resistance unit RN is constituted of a high resistance unit RN1 and a high resistance unit RN2 connected in series. Also, the reference electrode EG is separated into a first reference electrode EG1 and a second reference electrode EG2, and these electrodes are put in a state enabling electrical connection therebetween on the voltage detection circuit side. As a comparison to the circuit of the first example, one or more dummy resistors R(Dmy) are also provided between the resistors.

The dummy resistor is a resistor through which no current flows, and is provided in order to maintain electrical equivalence in the resistor circuit C10, maintain electrical stability, or reduce causes for error in manufacturing the resistor during the manufacturing process. The circuit configuration of the high voltage detection device is not limited thereto, and the shape and arrangement of the resistors may be changed as long as the basic voltage detection function can be exhibited.

The above-mentioned high voltage detection device can be accommodated in one semiconductor package. The functions of each circuit may be installed in the package so as to be distributed between the resistor chip and the amplifier chip.

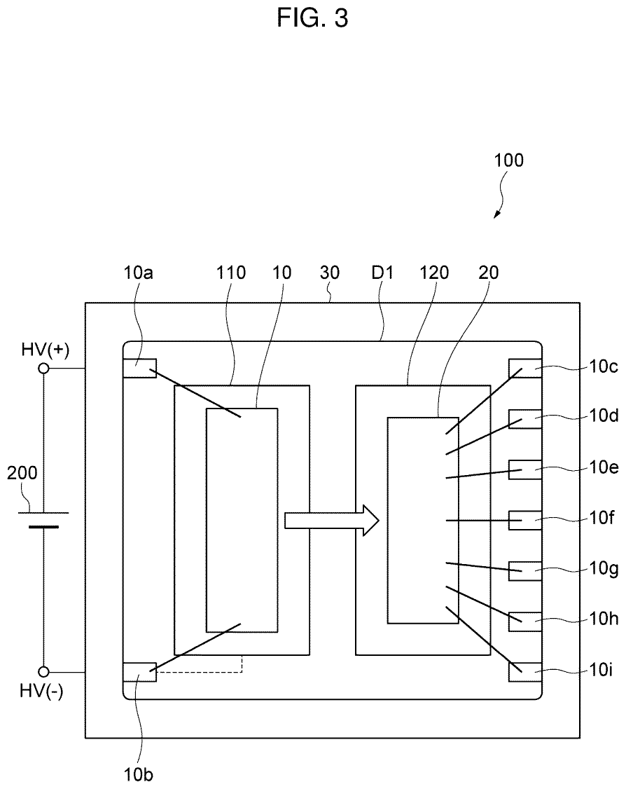

FIG. 3 is a plan view of a semiconductor package 100 equipped with a high voltage detection device. FIG. 3 shows a state in which a top lid is removed.

The semiconductor package 100 comprises a case 30 having a recess D1. The case 30 is made of an insulating material such as a resin or a ceramic. The semiconductor package 100 includes a resistor chip 10 (semiconductor device) disposed on a first die pad 110 in the recess D1, and an amplifier chip 20 (semiconductor device) disposed on a second die pad 120 in the recess D1. An open end of the recess D1 of the semiconductor package 100 is sealed with a lid (not shown), and therefore, the inside of the recess D1 is a closed-off space. The lid can be made of an insulating material such as a resin, and the inside of the recess D1 may be filled with a gas or with an insulating material. The first die pad 110 and the second die pad 120 have applied thereto a suitable potential such as ground potential via a lead frame. Also, the potential of the first die pad 110 may be set high as necessary, for example.

The resistor chip 10 includes the above-mentioned resistor circuit C10. The amplifier chip 20 includes the above-mentioned voltage detection circuit C20. Thus, the output voltage of the resistor chip 10 is inputted to the amplifier chip 20. The amplifier chip 20 outputs an output voltage Vout based on the detected voltage.

The positive electrode terminal of a battery 200 is electrically connected to a first inner lead 10a, and is connected to a first electrode of the resistor chip 10 via a bonding wire. The negative electrode terminal of the battery 200 is electrically connected to a second inner lead 10b, and is connected to a second electrode of the resistor chip 10 via a bonding wire.

Each terminal of the amplifier chip 20 can be connected, via a bonding wire, to a third inner lead 10c, a fourth inner lead 10d, a fifth inner lead 10e, a sixth inner lead 10f, a seventh inner lead 10g, an eighth inner lead 10h, and a ninth inner lead 10i.

For example, a power source voltage Vcc is applied to the third inner lead 10c and inputted to the amplifier chip 20. A ground potential GND is applied to the ninth inner lead 10i and inputted to the amplifier chip 20. The sixth inner lead 10f can output an output voltage Vout. A monitor signal based on the potential of the above-mentioned first output electrode EP (FIG. 1) can be outputted from the fourth inner lead 10d. A monitor signal based on the potential of the above-mentioned second output electrode EN (FIG. 2) can be outputted from the eighth inner lead 10h. The fifth inner lead 10e and the seventh inner lead 10g can be used for other applications as necessary.

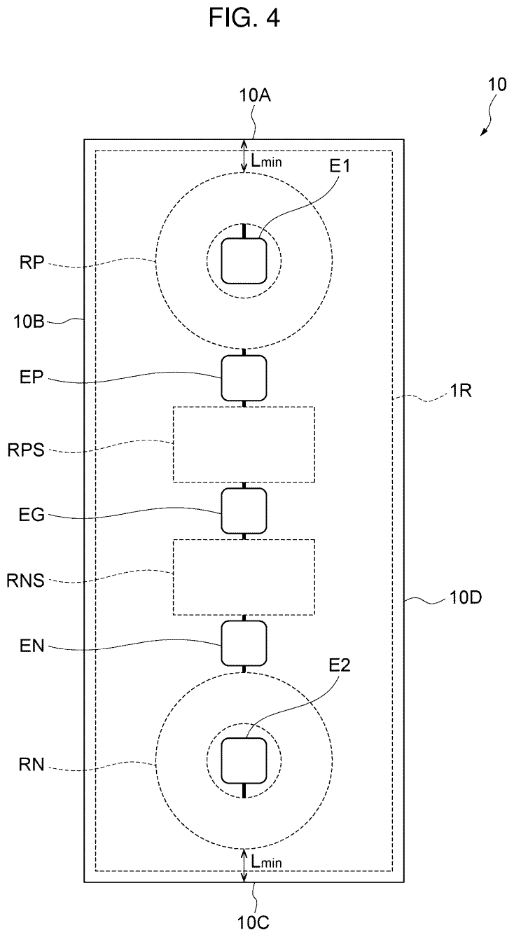

FIG. 4 is a plan view of the resistor chip 10.

The resistor chip 10 is configured by forming an insulating layer on a semiconductor substrate, and embedding a resistor in the insulating layer. The resistor chip 10 is rectangular in a plan view, includes a first side face 10A, a second side face 10B, a third side face 10C, and a fourth side face 10D, and an annular conductor 1R can be embedded in the insulating layer along the foregoing side faces. The annular conductor 1R can be constituted of an annular body made of a metallic material (copper, e, g.), and as necessary, an annular body made of another material (e.g., resistor material CrSi) electrically connected via a via electrode (tungsten, e.g.) to the top or bottom of the metallic material may be provided. The annular body can contribute to an improvement in watertightness and electrical stability.

In a plan view, the resistor chip 10 includes the first high resistance unit RP disposed so as to surround the first electrode E1, and the second high resistance unit RN disposed so as to surround the second electrode E2. The resistor chip 10 includes the low resistance units (RPS, RNS) for voltage detection. The low resistance units (RPS, RNS) are electrically connected to the first high resistance unit RP and the second high resistance unit RN, and have lower resistances than the first high resistance unit RP and the second high resistance unit RN.

In this example, in a plan view, the first high resistance unit RP, the first output electrode EP, the first low resistance unit RPS, the reference electrode EG, the second low resistance unit RNS, the second output electrode EN, and the second high resistance unit RN are arrayed along one direction. The first output electrode EP is positioned between the first high resistance unit RP and the first low resistance unit RPS. The second output electrode EN is positioned between the second high resistance unit RN and the second low resistance unit RNS. On a first layer, in which embedded wiring lines that make the above electrical connections are formed, is formed a second layer in which the high resistance units (RP, RPN) and the low resistance units (RPS, RNS), which are connected to the embedded wiring lines through via electrodes, are formed. Positioned closer to the substrate surface side than the second layer is a third layer in which the first electrode E1 and the second electrode E2, which are connected to the embedded wiring lines through the via electrodes, are formed.

In a plan view, the minimum distance between the first high resistance unit RP and the first side face 10A of the semiconductor chip (semiconductor substrate) is Lₘᵢₙ . Additionally, the minimum distance between the second high resistance unit RN and the third side face 10C of the semiconductor chip (semiconductor substrate) is also Lₘᵢₙ . The minimum distance Lₘᵢₙ may be set to 20 μm to 1,000 μm, inclusive. The minimum distance Lₘᵢₙ can more specifically be set to 40 μm to 160 μm, inclusive. An exemplary value for the minimum distance Lₘᵢₙ in a given design may be 58 μm. The lower limit for the minimum distance Lₘᵢₙ can be set according to limitations in machining such as dicing. If the minimum distance Lₘᵢₙ falls below the lower limit, the margin for dicing is reduced, which makes the high resistance unit more susceptible to side face effects after cutting. The dimension cut by the dicing blade can be set to 20 μm on one side of the dicing blade. Dicing can also be performed with a laser beam instead of a dicing blade. In the case of a design in which the distance from the high resistance unit to the side face position of the chip becomes far, the case of another circuit such as a large-scaled integrated circuit (LSI) being installed in the same chip, or the like, the minimum distance Lₘᵢₙ is increased, and can be set to 1,000 μm or less, for example. In the semiconductor device of this disclosure, the high resistance unit can be disposed close to the chip edge.

In an annular high resistance unit, it is possible to reduce the rate of change in potential in relation to distance in the vicinity of the first electrode E1 or the second electrode E2, and to reduce the intensity of the electric field around the electrode. Thus, it is possible to increase the breakdown voltage of the resistor chip 10. On the peripheral edge of the annular high resistance unit, if the potential is reduced, the effect on the chip side face can also be reduced, and thus, the resistor can be stably operated even with a small minimum distance Lₘᵢₙ . The range in the above-mentioned minimum distance Lₘᵢₙ is a value that can be set when providing an annular high resistance unit.

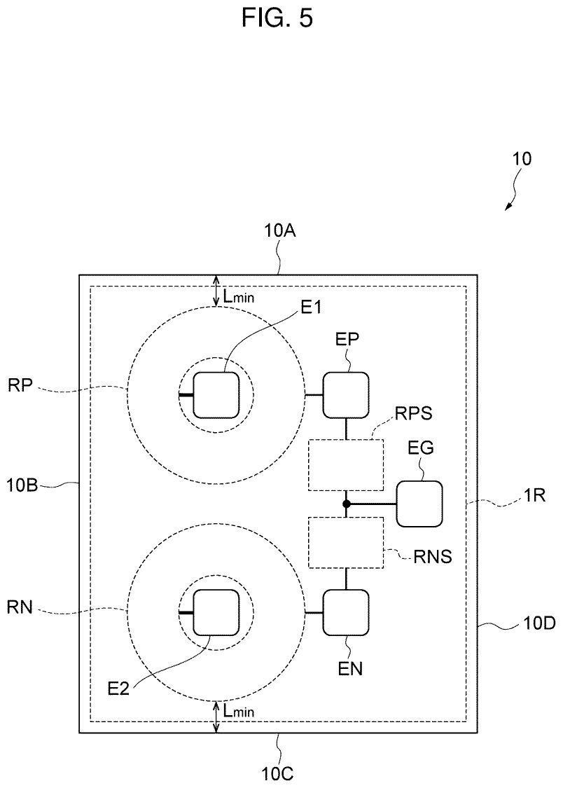

FIG. 5 is a plan view of the resistor chip 10 according to another arrangement example.

The resistor chip 10 according to this example differs in the following manner from the resistor chip shown in FIG. 4, and is otherwise the same as the resistor chip of FIG. 4.

In this example, in a plan view, the first output electrode EP is positioned to the side of the first high resistance unit RP. Also, the second output electrode EN is positioned to the side of the second high resistance unit RN. Additionally, the first low resistance unit RPS and the second low resistance unit RNS are disposed between the first output electrode EP and the second output electrode EN. In other words, the first output electrode EP, the second output electrode EN, the first low resistance unit RPS, and the second low resistance unit RNS are not positioned on a line connecting the first electrode E1 and the second electrode E2. The reference electrode EG is electrically connected to the connection point between the first low resistance unit RPS and the second low resistance unit RNS.

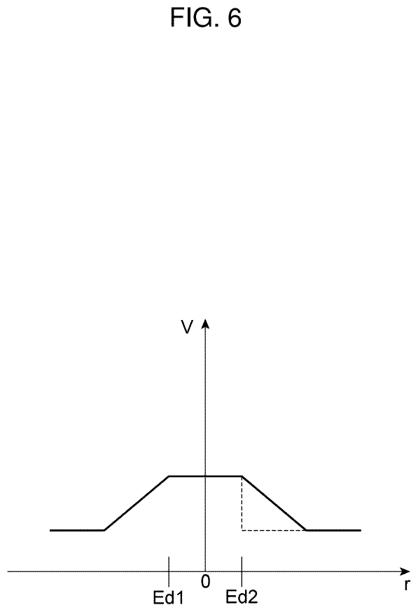

FIG. 6 is a graph showing the relationship between a distance r from the center of a first electrode E1 or a second electrode E2 (see FIG. 4 or 5), and a voltage V.

The centroid position of the first electrode E1 (or the second electrode E2) is designated as an origin point 0, and in a plan view, the position of one edge of the electrode along one direction is designated as a first position Ed1, and the position of the other edge is designated as a second position Ed2. If the high resistance unit spreads to only the first position Ed1 side of the first electrode E1, the voltage V (potential) at the second position Ed2 side sharply decreases as the distance R increases, as indicated by the dotted line, thereby increasing the intensity of the electric field and causing damage. In the resistor chip according to an embodiment, the high resistance unit is provided so as to surround the first electrode E1 (or the second electrode E2), and thus, even on the side of the second position Ed2, the voltage V (potential) decreases gradually as the distance r increases, as indicated by the solid line, which reduces the intensity of the electric field, thereby mitigating damage. If a spiral resistor is used as in the structure of Embodiment 1, the magnetic flux generated in the center of the spiral is understood to contribute to an increase in durability against a surge voltage.

Examples of shapes of the annular high resistance unit will be described.

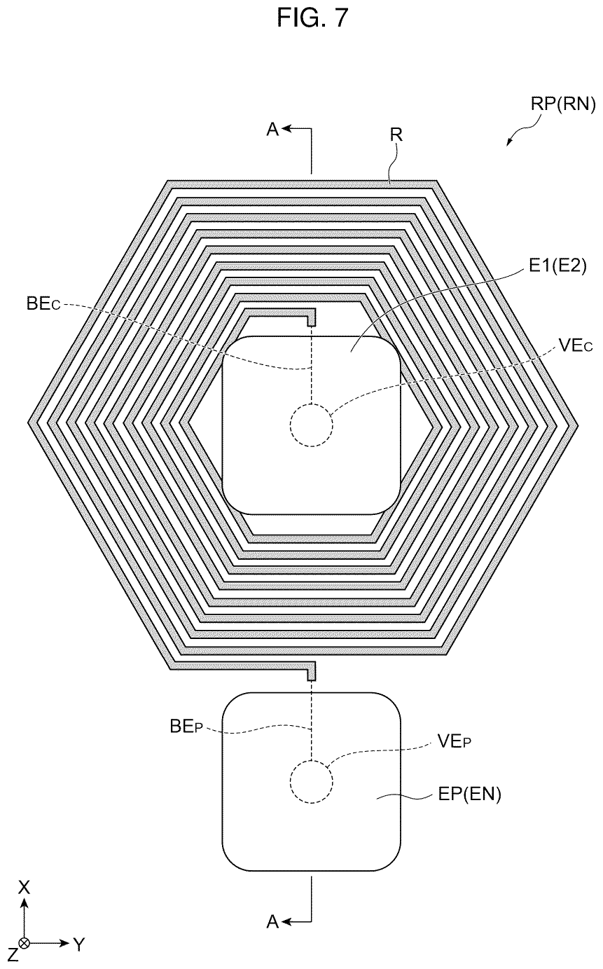

FIG. 7 is a plan view of the high resistance unit according to Embodiment 1.

FIG. 7 shows the first high resistance unit RP (or second high resistance unit RN), which includes a resistor R. The resistor R is a resistor layer made of a resistor material, and linearly extends so as to surround the first electrode E1 (or second electrode E2) in a plan view. Specifically, the shape of the resistor R of the first high resistance unit RP and the shape of the resistor R of the second high resistance unit RN are respectively spiral in a plan view. More specifically, the shape of the resistor R is a polygonal spiral, and in FIG. 7, linear resistors extending along the respective sides of a hexagon are connected to each other to form a spiral. The polygon may have six or more sides. However, the polygon has at least three sides. This resistor, which extends linearly, may be referred to as a linear resistor.

The direction from the first output electrode EP (or second output electrode EN) towards the first electrode E1 (second electrode E2) is designated as the X axis direction, the thickness direction of the resistor chip is designated as the Z axis direction, and the direction perpendicular to both the X axis and the Z axis is designated as the Y axis direction. The first electrode E1 (second electrode E2) is physically and electrically connected to an embedded wiring line BE_{C} positioned therebelow, via a via electrode VE_{C}. The embedded wiring line BE_{C} is physically and electrically connected to a first end (end closer to the center) of the resistor R positioned thereabove. A second end (end closer to the peripheral edge) of the resistor R is physically and electrically connected to an embedded wiring line BE_{P} positioned therebelow via a via electrode. The embedded wiring line BE_{P} extends to below the first output electrode EP (second output electrode EN), and is physically and electrically connected to the first output electrode EP (second output electrode EN) via a via electrode VE_{P}.

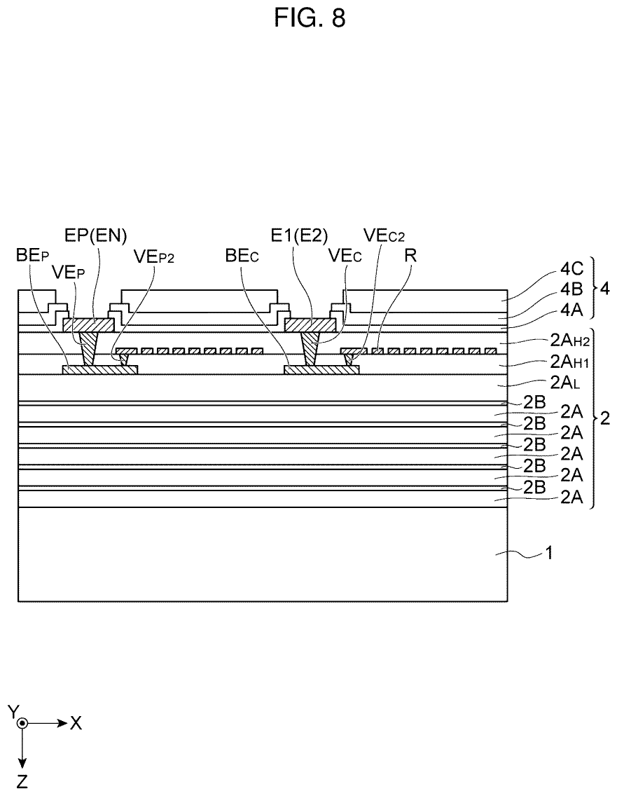

FIG. 8 is a diagram showing a vertical cross-sectional configuration (cross-sectional view along the arrow A-A in FIG. 7) of the high resistance unit.

The resistor chip includes a semiconductor substrate 1, an insulating layer 2 provided on the semiconductor substrate 1, and a protective film 4 provided on the insulating layer 2.

The insulating layer 2 includes a plurality of stacked dielectric layers (first dielectric layer 2A, second dielectric layer 2B). At least one of the plurality of dielectric layers (first dielectric layer 2A) includes a silicon oxide as the material thereof. At least one of the plurality of dielectric layers (second dielectric layer 2B) includes a silicon nitride as the material thereof. In this example, the first dielectric layers 2A and the second dielectric layers 2B are alternately stacked. The silicon oxide of this example is SiO₂, but as necessary the element compositional ratio may be modified, and other elements may be included. The silicon nitride of this example is Si₃N₄, but as necessary the element compositional ratio may be modified, and other elements may be included. The thickness of the insulating layer 2 may be 5 μm to 50 μm, inclusive, for example.

The insulating layer 2 includes a lower dielectric layer 2A_{L} formed on the topmost second dielectric layer 2B, and a first higher dielectric layer 2A_{H1} and a second higher dielectric layer 2A_{H2} formed on the lower dielectric layer 2AL. Exemplary materials constituting the lower dielectric layer 2AL, the first higher dielectric layer 2A_{H1}, and the second higher dielectric layer 2AH2 are the same as those of the first dielectric layer 2A.

The protective film 4 includes a first protective film 4A, a second protective film 4B, and a third protective film 4C stacked in the stated order on the insulating layer 2. The first protective film 4A can be made of an inorganic insulating material such as a silicon oxide or a silicon nitride, and is made of SiO₂, for example. The second protective film 4B is formed on the first protective film 4A. The second protective film 4B is made of an inorganic insulating material such as a silicon oxide or a silicon nitride, and may be made of the same material as or a different material from the first protective film 4A, but is made of a silicon nitride, for example. The third protective film 4C is made of a resin such as polyimide (insulating material).

The protective film 4 is removed from areas directly above the first electrode E1 (second electrode E2) and the first output electrode EP (second output electrode EN). Thus, the top surfaces of the first electrode E1 (second electrode E2) and the first output electrode EP (second output electrode EN) are exposed. A wiring line (bonding wire, wiring pattern) is connected to the top surfaces of the electrodes (electrode pads).

The embedded wiring line BEC and the embedded wiring line BEP are formed on the lower dielectric layer 2A_{L}. The resistor layer constituting the resistor R is formed on the first higher dielectric layer 2A_{H1}. The first electrode E1 (second electrode E2) is formed on the second higher dielectric layer 2A_{H2}. The via electrode VEC connects the first electrode E1 (second electrode E2) to the embedded wiring line BEC. The via electrode VE_{C2} connects the embedded wiring line BE_{C} to one end of the resistor R towards the annular center. The via electrode VE_{P2}connects one end on the peripheral edge of the annular resistor R to the embedded wiring line BE_{P}. The via electrode VE_{P} connects the embedded wiring line BEP to the first output electrode EP (second output electrode EN).

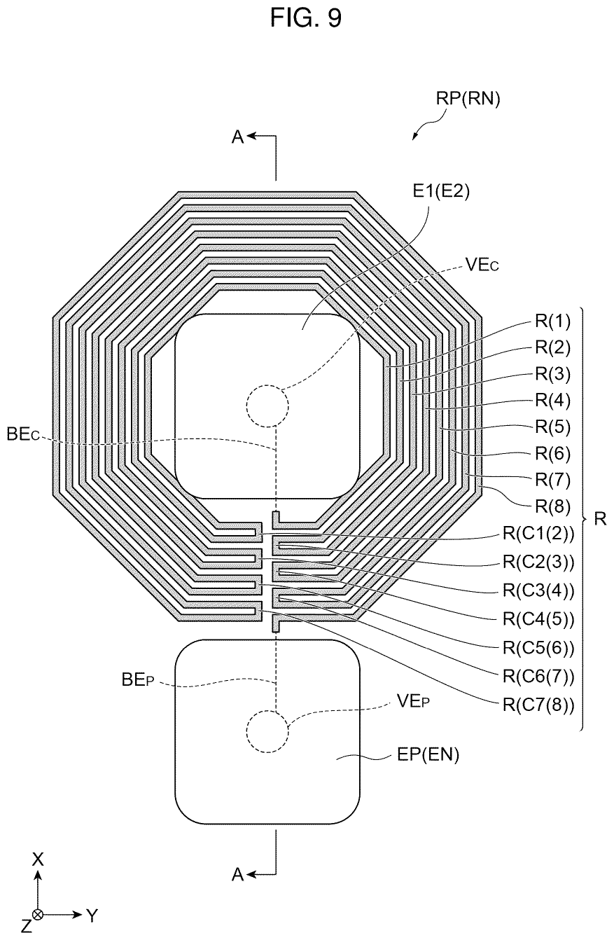

FIG. 9 is a plan view of the high resistance unit according to Embodiment 2.

FIG. 9 shows the first high resistance unit RP (or second high resistance unit RN), which includes the resistor R. The resistor R is a resistor layer made of a resistor material, and linearly extends so as to surround the first electrode E1 in a plan view. Specifically, the shape of the resistor R of the first high resistance unit RP and the shape of the resistor R of the second high resistance unit RN fold back at a specific position in the peripheral direction in a plan view.

Regarding the first high resistance unit RP, n is a natural number and N is a natural number (3≤N). In this example, N=8, and the resistor R includes eight annular linear regions (R(n): first linear region R(1) to eighth linear region R(8)). The shape of the resistor R of the first high resistance unit RP includes N linear regions R(n) extending along the peripheral direction of the first electrode E1 in a plan view. One linear region R(n) is the first linear region R(1), for example, and in the first linear region R(1), seven linear resistors are disposed along seven sides of an octagon, while two linear resistors are disposed along the remaining side of the octagon.

The resistor R includes a first connection region R(Cn(n+1)) that connects, in the radial direction, respective first ends of an nth linear region R(n) from the inside and an (n+1)th linear region R(n+1) from the inside, which are adjacent to each other in the radial direction, among the linear regions R(n). The resistor R includes a first connection region R(C1(2)) that connects, in the radial direction, respective first ends of the first linear region R(1) and the second linear region R(2), for example.

The resistor R includes a second connection region R(Cn+1(n+2)) that connects, in the radial direction, respective second ends of an (n+1)th linear region R(n+1) from the inside and an (n+2)th linear region R(n+2) from the inside, which are adjacent to each other in the radial direction, among the linear regions R(n). The resistor R includes a second connection region R(C2(3)) that connects, in the radial direction, respective first ends of a second linear region R(2) and a third linear region R(3), for example.

In FIG. 9, linear resistors extending along the respective sides of an octagon are connected to each other to form the above-mentioned fold-back structure. The polygon may have eight or more sides. However, the polygon has at least three sides.

Regarding the second high resistance unit RN, where m is a natural number and M is a natural number (3≤N), m is a substitute for n described above, and similarly, M is a substitute for N.

In this case, the shape of the resistor R of the second high resistance unit RN includes M linear regions R(m) (first linear region R(1) to eighth linear region R(8)) extending along the peripheral direction of the second electrode E2 in a plan view. The resistor R includes a third connection region R(Cm(m+1)) that connects, in the radial direction, respective first ends of an mth linear region R(Cm) from the inside and an (m+1)th linear region R(m+1) from the inside, adjacent to each other in the radial direction, among the linear regions of the second high resistance unit RN. The resistor R includes a fourth connection region R(Cm+1(m+2)) that connects, in the radial direction, respective second ends of an (m+1)th linear region R(m+1) from the inside and an (m+2)th linear region R(m+2) from the inside, adjacent to each the other in the radial direction, among the linear regions of the second high resistance unit RN. Values of n and m are typically odd numbers.

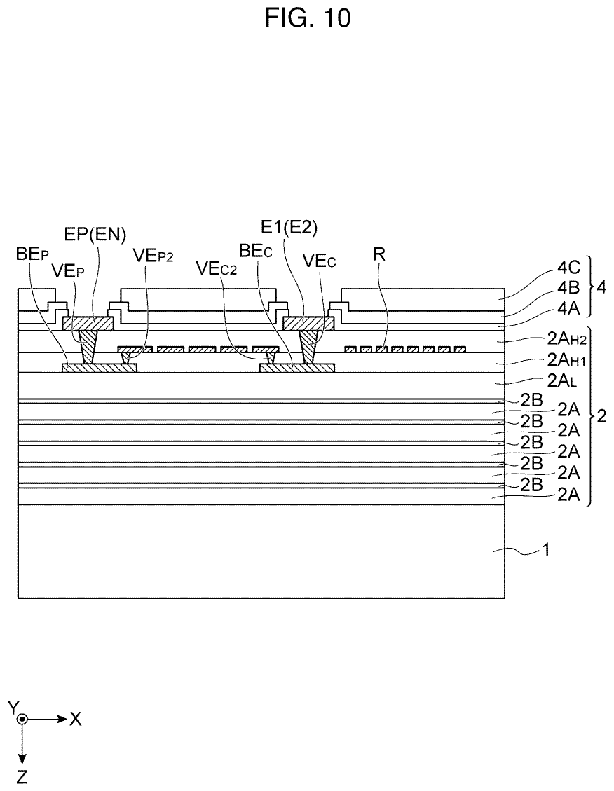

FIG. 10 is a diagram showing a vertical cross-sectional configuration (cross-sectional view along the arrow A-A in FIG. 9) of the high resistance unit.

The resistor chip includes a semiconductor substrate 1, an insulating layer 2 provided on the semiconductor substrate 1, and a protective film 4 provided on the insulating layer 2. In this semiconductor chip, the configuration differs from the high resistance unit of Embodiment 1 (FIGS. 7 and 8) in that the resistor R has the above-mentioned fold-back structure, but otherwise has the same structure as the high resistance unit of Embodiment 1.

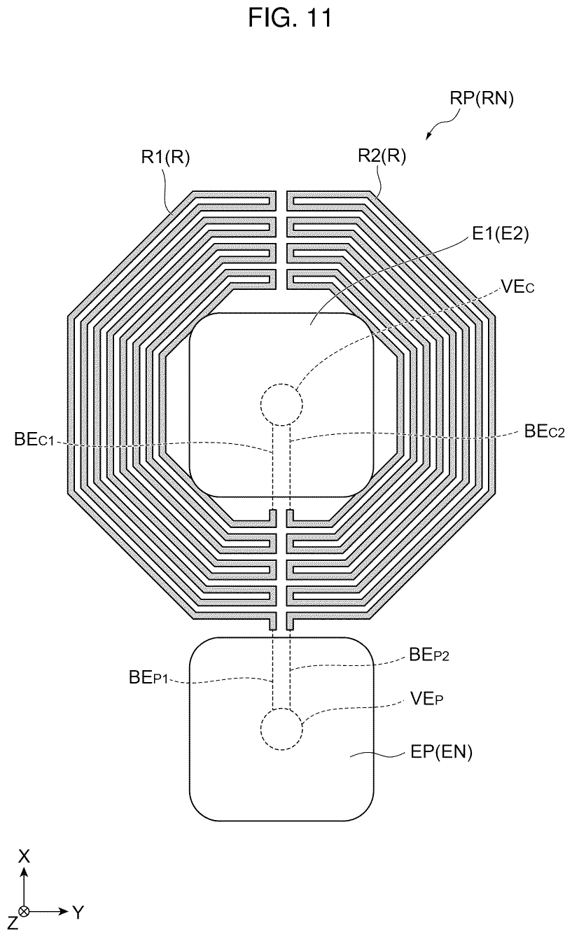

FIG. 11 is a plan view of the high resistance unit according to Embodiment 3.

FIG. 11 shows the first high resistance unit RP (or second high resistance unit RN), which includes a resistor R (first resistor R1, second resistor R2) constituting a high resistance unit. The resistor R is a resistor layer made of a resistor material, and linearly extends so as to surround the first electrode E1 (or second electrode E2) in a plan view.

The shape of the first resistor R1 folds back at a specific position in the peripheral direction in a plan view. The shape of the second resistor R2 folds back at a specific position in the peripheral direction in a plan view. The structures of the first resistor R1 and the second resistor R2 differ from that of the resistor R of Embodiment 2 in terms of the fold-back position. In Embodiment 2, the linear resistor folds back after extending from 0° to almost 360°, but each resistor (R1, R2) of this example extends from 0° to almost 180° and then folds back. This example has a structure in which the resistor of Embodiment 2 is split in two. By modifying the fold-back position, the resistor can be split into a plurality of sections, such as three, four, five, or six sections.

The first electrode E1 (second electrode E2) is physically and electrically connected to an embedded wiring line BE_{C1} and an embedded wiring line BE_{C2} positioned therebelow, via a via electrode VE_{C}. These embedded wiring lines may be the same wiring line.

The embedded wiring line BE_{C1} is physically and electrically connected to a first end (end closer to the center) of the first resistor R1 positioned thereabove. A second end (end closer to the peripheral edge) of the first resistor R1 is physically and electrically connected to an embedded wiring line BEP1 positioned therebelow via a via electrode. The embedded wiring line BEP1 extends to below the first output electrode EP (second output electrode EN), and is physically and electrically connected to the first output electrode EP (second output electrode EN) via a via electrode VE_{P}.

Similarly, the embedded wiring line BE_{C2} is physically and electrically connected to a first end (end closer to the center) of the second resistor R2 positioned thereabove. A second end (end closer to the peripheral edge) of the second resistor R2 is physically and electrically connected to an embedded wiring line BE_{P2} positioned therebelow via a via electrode. The embedded wiring line BE_{P2} extends to below the first output electrode EP (second output electrode EN), and is physically and electrically connected to the first output electrode EP (second output electrode EN) via a via electrode VE_{P}.

The embedded wiring line BE_{C1} and the embedded wiring line BE_{P} are formed on the above-mentioned lower dielectric layer 2A_{L} (see FIG. 10). The resistor layer constituting the resistor R is formed on the first higher dielectric layer 2A_{H1} (see FIG. 10). The first electrode E1 (second electrode E2) is formed on the second higher dielectric layer 2A_{H2} (see FIG. 10).

The cross-sectional structures and connective relationship of the first resistor R1 and the second resistor R2 are similar to that of Embodiment 2 (see FIG. 10). In other words, the via electrode VEC towards the center connects the first electrode E1 (second electrode E2) to the embedded wiring line BEC of FIG. 10 (embedded wiring line BE_{C1} and embedded wiring line BE_{C2} of FIG. 11). The via electrode VE_{C2} of FIG. 10 connects the embedded wiring line BEC (embedded wiring line BEC1 and embedded wiring line BE_{C2} of FIG. 11) to one end of the resistor R towards the annular center. The via electrode VE_{P2} of FIG. 10 connects one end on the peripheral edge of the annular resistor R to the embedded wiring line BE_{P} (embedded wiring line BE_{P1} and embedded wiring line BE_{P2} of FIG. 11). The via electrode VE_{P} connects the embedded wiring line BE_{P} of FIG. 10 (embedded wiring line BEP1 and embedded wiring line BE_{P2} of FIG. 11) to the first output electrode EP (second output electrode EN).

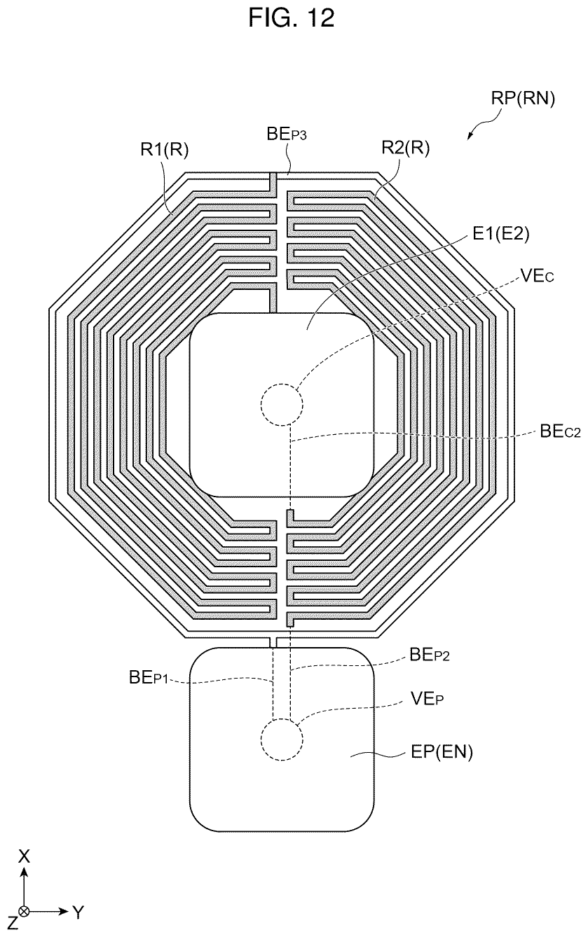

FIG. 12 is a plan view of the high resistance unit according to Embodiment 4.

FIG. 12 shows the first high resistance unit RP (or second high resistance unit RN), which includes a resistor R (first resistor R1, second resistor R2) constituting a high resistance unit. The resistor R is a resistor layer made of a resistor material, and linearly extends so as to surround the first electrode E1 (or second electrode E2) in a plan view. The difference from the high resistance unit of Embodiment 3 is that the orientation of the first resistor R1 is rotated by 180° in a plan view, and an embedded wiring line BE_{P3} is connected to the outer end of the first resistor R1, which is consequently positioned on the opposite side to the first output electrode EP (second output electrode EN). The configuration is otherwise the same as structure of Embodiment 3. The embedded wiring line BE_{P3} is continuous with the embedded wiring line BE_{P1}, which is connected to the first output electrode EP (second output electrode EN). In other words, the embedded wiring line BEP3 can be formed in the same layer as the embedded wiring line BE_{P1}.

In the structure of Embodiment 4, the position at the outer end of the resistor can be connected to the first output electrode EP (second output electrode EN) no matter where the outer end of the resistor is by being led around, and this structure can easily be used in a resistor divided into two or more sections.

There is no particular limitation on the structure of the low resistance unit for voltage detection, but an exemplary structure will be described.

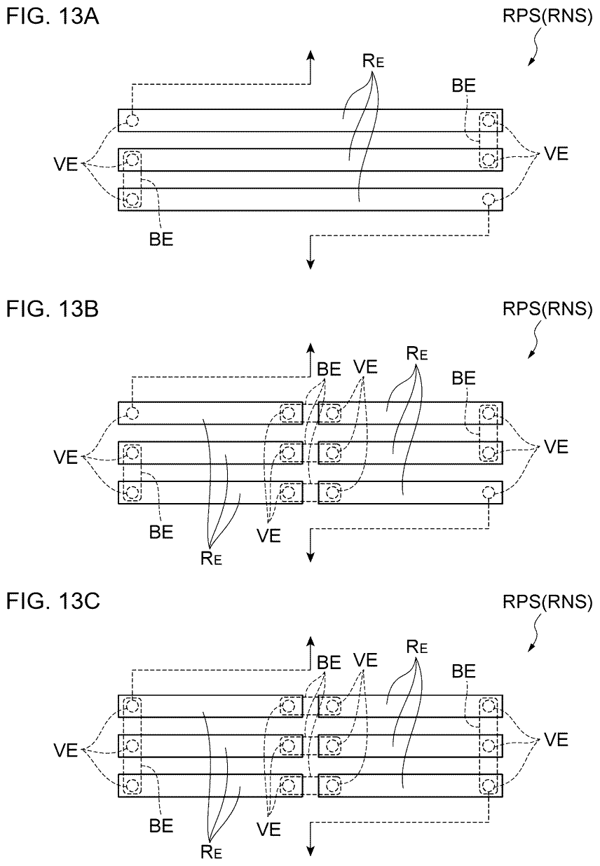

FIGS. 13A, 13B, and 13C are plan views of low resistance units for voltage detection.

The first low resistance unit RPS (or second low resistance unit RNS) includes a plurality of linear resistors R_{E} extending in a line. The via electrode VE is provided below the edge of each resistor R_{E}, and the via electrodes VE are physically and electrically connected to the embedded electrodes BE positioned therebelow. The number of linear resistors may be three or more, or less than three.

In the example shown in FIG. 13A, three linear resistors R_{E} are shown, and the first end of the linear resistor R_{E} in the first row from the top of the drawing is connected to the first end of the linear resistor R_{E} in the second row, via the via electrodes VE and the embedded electrode BE. The second end of the linear resistor R_{E} in the second row is connected to the second end of the linear resistor R_{E} in the third row, via the via electrodes VE and the embedded electrode BE.

Specifically, the low resistance unit shown in FIG. 13A includes a plurality of linear resistors R_{E}, and in a plan view, each of the linear resistors R_{E} extends along the first direction (horizontal direction in drawing). In a plan view, the plurality of linear resistors R_{E} are disposed along a second direction (vertical direction in drawing) that is perpendicular to the first direction. k is a natural number, and is an odd number in this example. The first side end (e.g., right side of drawing) of the kth (e.g., first from the top) linear resistor R_{E} is electrically connected to the first side end (e.g., right side of drawing) of the (k+1)th (e.g., second) linear resistor R_{E} adjacent thereto. The second side end (e.g., left side of drawing) of the (k+1)th (e.g., second) linear resistor R_{E} is electrically connected to the second side end (e.g., left side of drawing) of the (k+2)th (e.g., third) linear resistor R_{E} adjacent thereto.

In the example shown in FIG. 13B, the linear resistors shown in FIG. 13A are split in two in each row, such that a plurality of linear resistors R_{E} are disposed in each row. Thus, a total of six linear resistors R_{E} are shown. Opposing edges of a pair of adjacent linear resistors R_{E} in the same row are connected to each other via the via electrodes VE and the embedded electrode BE.

In other words, in the structure of FIG. 13B, the linear resistors R_{E} in each row shown in FIG. 13A are configured such that two or more linear resistors extending along the first direction (horizontal direction in drawing) are connected in series.

In the example shown in FIG. 13C, the first ends of all the linear resistors R_{E} shown in FIG. 13B are connected to each other via the via electrodes VE and a common embedded electrode BE, and the second ends of all the linear resistors R_{E} are connected to connected to each other via the via electrodes VE and a common embedded electrode BE. In this example, it is possible to achieve a lower combined resistance as compared to the resistor shown in FIG. 13B.

Specifically, the low resistance unit shown in FIG. 13C includes a plurality of rows of linear resistors (linear resistors configured such that two or more linear resistors R_{E} are connected in series per row), and in a plan view, each row of the linear resistors extends along the first direction (horizontal direction in drawing). In a plan view, the plurality of rows of linear resistors are disposed along a second direction (vertical direction in drawing) that is perpendicular to the first direction. k is a natural number, and is an odd number in this example. Both ends of the kth (e.g., first from the top) row of the linear resistors are electrically connected to both ends of the (k+1)th (e.g., second) row of the linear resistors adjacent thereto.

In this example, the respective linear resistors in each row are configured such that two or more linear resistors R_{E} extending along the above-mentioned first direction are connected in series. Each row of linear resistors may be constituted of one linear resistor R_{E}.

The vertical cross-sectional structure of the low resistance units (RPS, RNS) for detection can be made the same as the vertical cross-sectional structure of the high resistance units (RP, RN), with the exception of the plan view shape. In other words, the above-mentioned linear resistors R_{E}, the via electrode VE, and the embedded electrodes BE (embedded wiring lines) are embedded in the insulating layer formed on the semiconductor substrate.

The low resistance unit may be constituted of a wide resistor layer extending in the first direction in a plan view. In this case, the resistor layer is set to be wide in the second direction perpendicular to the first direction. Specifically, the width of the resistor layer is greater than the width of the linear region in the resistors constituting the first high resistance unit and the second high resistance unit. If the shape of the resistors constituting the high resistance units is spiral, then the width direction of the linear region is a direction perpendicular to the direction in which the spiral extends. If the shape of the resistors constituting the high resistance units meanders to form a fold-back shape, then the width direction of the linear region is a direction perpendicular to the lengthwise direction of the resistors that extend while meandering. This resistor layer can include CrSi, but can also include another resistor material constituting a resistor layer to be described below.

The material of each element will be explained below.

The semiconductor substrate 1 (FIGS. 8 and 10) can be conductive. The impurity concentration of the semiconductor subtrate 1 may be 5×10⁻³ to 5×10¹⁴cm⁻³, inclusive. The thickness of the semiconductor substrate 1 may be 50 μm to 800 μm, inclusive. The semiconductor substrate 1 can be made of silicon (Si), but a compound semiconductor such as SiC or SiGe can alternatively be used.

The material of the resistor layer (linear resistor) constituting the resistor R is a resistor material having a higher resistivity than polysilicon. Specifically, the material of the resistor (resistor layer) is a material including chromium (Cr) and silicon (Si), and is CrSi, CrSiC, or CrSiN. Other materials can be used. In other words, the material of the resistor layer constituting the resistor can specifically be made of at least one metallic compound selected from a group consisting of CrSi, CrSiN, CrSiO, TaN, and TiN. The resistor layer constituting the resistor can be formed by sputtering or the like using a target including a resistor material. Plating can also be employed depending on the type of material used for the resistor R. The material of the resistor R may be a single resistor material, but may be a combination of a plurality of resistor materials. A thickness Rd of each resistor layer constituting the resistor R can be set to 1 nm≤Rd≤5 nm. By setting the thickness Rd to less than or equal to the upper limit, the resistance can be sufficiently increased, while if the thickness Rd is set to greater than or equal to the lower limit, the durability and strength of the resistor layer can be maintained.

A metallic material such as aluminum (Al) or copper (Cu) can be used as the material for the first electrode E1, the second electrode E2, and the embedded electrode (embedded wiring line). A high melting point metal such as tungsten (W) can be used as the material for each type of via electrode, but another electrode material can also be used.

As described above, the resistor chip includes the first high resistance unit RP, the second high resistance unit RN, and the low resistance units (RPS, RNS) for voltage detection that connect the foregoing. When a high voltage is applied to the first electrode E1 and the second electrode E2 (electrode pads), the change in voltage per unit length is sharp in the vicinity of the electrodes, and the intensity of the electric field therein tends to be high. If the intensity of the electric field is high, and in particular, if a surge voltage is inputted, the vicinity of the electrode pads tends to receive damage. In the resistor chip of the embodiments, the first high resistance unit RP and the second high resistance unit RN surround the electrodes in an annular form, thereby spreading the potential distribution in the horizontal direction, reducing the voltage change per unit length, reducing the intensity of the electric field, and mitigating the concentration of the electric field, thereby mitigating damage to the electrode pads.

Note: As described above, the various embodiments of this disclosure can be defined as follows.
[A1] A semiconductor device, including: a semiconductor substrate 1; an insulating layer 2 provided on the semiconductor substrate 1; a first high resistance unit RP embedded in the insulating layer 2 and disposed so as to surround a first electrode E1 in a plan view; a second high resistance unit RN embedded in the insulating layer 2 and disposed so as to surround a second electrode E2 in a plan view; and low resistance units (RPS, RNS) for voltage detection that are electrically connected to the first high resistance unit RP and the second high resistance unit RN, and have lower resistances than the first high resistance unit RP and the second high resistance unit RN.
[A2] The semiconductor device according to [A1], wherein a shape of a resistor of the first high resistance unit RP and a shape of a resistor R of the second high resistance unit RN are respectively spiral in a plan view.
[A3] The semiconductor device according to [A1], wherein n is a natural number, and N is a natural number (3≤N), and wherein, in a plan view, a shape of a resistor R of the first high resistance unit RP includes: N linear regions extending along a peripheral direction of the first electrode E1; a first connection region that connects, in a radial direction, respective first ends of an nth linear region from inside and an (n+1)th linear region from the inside, which are adjacent to each other in the radial direction, among the linear regions; and a second connection region that connects, in the radial direction, respective second ends of the (n+1)th linear region from the inside and an (n+2)th linear region from the inside, which are adjacent to each the other in the radial direction, among the linear regions.
[A4] The semiconductor device according to [A3], wherein m is a natural number, and M is a natural number (3≤M), and wherein, in a plan view, a shape of a resistor of the second high resistance unit includes: M linear regions extending along a peripheral direction of the second electrode; a third connection region that connects, in the radial direction, respective first ends of an mth linear region from inside and an (m+1)th linear region from the inside, which are adjacent to each other in the radial direction, among the linear regions of the second high resistance unit; and a fourth connection region that connects, in the radial direction, respective second ends of the (m+1)th linear region from the inside and an (m+2)th linear region from the inside, which are adjacent to each the other in the radial direction, among the linear regions of the second high resistance unit.
[A5] The semiconductor device according to [A1], wherein, in a plan view, a minimum distance Lₘᵢₙ between the first high resistance unit and a side face of the semiconductor substrate is 1,000 μm or less, and a minimum distance Lₘᵢₙ between the second high resistance unit RN and the side face semiconductor substrate 1 is 1,000 μm or less.
[A6] The semiconductor device according to any one of [A1] to [A5], wherein the low resistance unit includes a plurality of linear resistors, wherein, in a plan view, each of the linear resistors extends in a first direction, wherein, in a plan view, the plurality of linear resistors are disposed along a second direction that is perpendicular to the first direction, and wherein, where k is a natural number, a first side end of the kth linear resistor is electrically connected to a first side end of the (k+1)th linear resistor adjacent thereto, and a second side end of the (k+1)th linear resistor is electrically connected to a second side end of the (k+2)th linear resistor adjacent thereto.
[A7] The semiconductor device according to [A6], wherein the respective linear resistors are configured such that two or more linear resistors extending along the first direction are connected in series.
[A8] The semiconductor device according to any one of [A1] to [A5], wherein the low resistance unit includes a plurality of rows of linear resistors, wherein, in a plan view, each row of the linear resistors extends in a first direction, wherein, in a plan view, the plurality of linear resistors are disposed along a second direction that is perpendicular to the first direction, and wherein, where k is a natural number, both ends of the kth linear resistor are electrically connected to both ends of the (k+1)th linear resistor adjacent thereto.
[A9] The semiconductor device according to [A8], wherein the respective rows of linear resistors are configured such that two or more linear resistors extending along the first direction are connected in series.
[A10] The semiconductor device according to any one of [A1] to [A5], wherein the low resistance unit includes a resistor layer extending in a first direction in a plan view, and wherein a width of the resistor layer along a second direction perpendicular to the first direction is greater than a width of the linear region in the resistors constituting the first high resistance unit and the second high resistance unit.
[A11] The semiconductor device according to [A10], wherein the resistor layer includes CrSi.

The various exemplary embodiments were described above, the invention is not limited to the exemplary embodiments, and various omissions, substitutions, and modifications may be made. Also, it is possible to combine elements of various embodiments to form another embodiment. Additionally, the various embodiments of this disclosure were described in this specification for the purpose of explanation, and it should be understood that various modifications can be made without departing from the scope and spirit of this disclosure. Thus, the various embodiments disclosed in this specification do not signify limitations to the invention, and the true scope and spirit of the invention is indicated by the attached claims.

What is claimed is:

1. A semiconductor device, comprising:
a semiconductor substrate;
an insulating layer provided on the semiconductor substrate;
a first high-resistance unit embedded in the insulating layer and disposed so as to surround a first electrode in a plan view;
a second high-resistance unit embedded in the insulating layer and disposed so as to surround a second electrode in a plan view; and
low-resistance units for voltage detection that are electrically connected to the first high-resistance unit and the second high-resistance unit, and have lower resistances than the first high-resistance unit and the second high-resistance unit.

2. The semiconductor device according to claim 1,
wherein a shape of a resistor of the first high-resistance unit is spiral in a plan view.

3. The semiconductor device according to claim 2,
wherein a shape of a resistor of the second high-resistance unit is spiral in a plan view.

4. The semiconductor device according to claim 1,
wherein n is a natural number, and N is a natural number (3≤N), and
wherein, in a plan view, a shape of a resistor of the first high-resistance unit includes:
N linear regions extending along a periphery of the first electrode;
a first connection region that connects, in a radial direction, respective first ends of an nth linear region from an inside and an (n+1)th linear region from the inside, which are adjacent to each other in the radial direction, among the linear regions; and
a second connection region that connects, in the radial direction, respective second ends of the (n+1)th linear region from the inside and an (n+2)th linear region from the inside, which are adjacent to each other in the radial direction, among the linear regions.

5. The semiconductor device according to claim 3,
wherein m is a natural number, and M is a natural number (3≤M), and
wherein, in a plan view, a shape of a resistor of the second high-resistance unit includes:
M linear regions extending along a peripheral direction of the second electrode;
a third connection region that connects, in the radial direction, respective first ends of an mth linear region from inside and an (m+1)th linear region from the inside, which are adjacent to each other in the radial direction, among the linear regions of the second high-resistance unit; and
a fourth connection region that connects, in the radial direction, respective second ends of the (m+1)th linear region from the inside and an (m+2)th linear region from the inside, which are adjacent to each other in the radial direction, among the linear regions of the second high-resistance unit.

6. The semiconductor device according to claim 1,
wherein, in a plan view,
a minimum distance Lₘᵢₙ between the first high-resistance unit and a side face of the semiconductor substrate is 1,000 μm or less.

7. The semiconductor device according to claim 6,
wherein, in a plan view,
a minimum distance Lₘᵢₙ between the second high-resistance unit and the side face of the semiconductor substrate is 1,000 μm or less.
